(19) United States
(12) Patent Application Publication
(10) Pub. No.: US 2013/0228864 A1
(43) Pub. Date: Sep. 5, 2013

(54) FIN FIELD EFFECT TRANSISTOR AND FABRICATION METHOD

(71) Applicant: SEMICONDUCTOR MANUFACTURING INTERNATIONAL CORP., Shanghai (CN)

(72) Inventor: FUMITAKE MIENO, Shanghai (CN)

(73) Assignee: Semiconductor Manufacturing International Corp., Shanghai (CN)

(21) Appl. No.: 13/777,264

(22) Filed: Feb. 26, 2013

(30) Foreign Application Priority Data
Mar. 2, 2012 (CN) 201210054233.0

(51) Int. Cl. H01L 29/66; H01L 29/78

(52) U.S. Cl. CPC H01L 29/66795; H01L 29/785
USPC 257/347; 438/479

(57) ABSTRACT

A fin field effect transistor (Fin FET) and a method for forming the Fin FET are provided. In an exemplary method, the Fin FET can be formed by providing a dielectric layer on a semiconductor substrate. The dielectric layer and the semiconductor substrate can be etched to form a groove including a second sub-groove, formed through the dielectric layer, and a first sub-groove, formed in the semiconductor substrate and connected to the second sub-groove. A fin can then be formed in the groove. The fin can have a top surface higher than a top surface of the dielectric layer. A gate structure can then be formed at least partially around a length portion of the fin on the top surface of the dielectric layer.

### CROSS REFERENCE TO RALATED APPLICATIONS

This application claims priority to Chinese patent application No. 201210054233.0, filed on Mar. 2, 2012, and entitled “FIN FIELD EFFECT TRANSISTOR AND METHOD FOR FORMING THE SAME”, the entire disclosure of which is incorporated herein by reference.

### FIELD OF THE DISCLOSURE

The present disclosure generally relates to the field of semiconductor manufacturing technology and, more particularly, to a fin field effect transistor (Fin FET) and a method for forming the same.

### BACKGROUND OF THE DISCLOSURE

With increasing development of semiconductor technology, and with downsizing of process nodes, the gate-last technology has been widely used to achieve desired threshold voltage and to improve device performance. However, when critical dimensions of devices further decrease, even if the gate-last technology is used, conventional MOS field effect transistors are still not able to meet the requirements on the device performance. For this reason, multi-gate devices have been widely used.

Fin field effect transistors (Fin FETs) are multi-gate devices which are widely used nowadays. FIG. 1 is a perspective view of a common type of Fin FET. As shown in FIG. 1, the Fin FET includes a substrate 10 and a fin structure 14 protruding from the substrate 10. A dielectric layer 11 is disposed to cover the substrate 10 on opposite sides of the fin structure 14 and to cover a portion of sidewalls of the fin structure 14. A gate structure 12, including a gate dielectric layer and a gate electrode layer (not shown in FIG. 1), is disposed on the dielectric layer 11. The gate structure 12 stretches over the fin structure 14, partially covering the top surface and sidewalls of the fin structure 14. A source region and a drain region are respectively disposed within the fin structure 14 on opposite sides of gate structure 12. On the top surface and sidewalls of the fin structure 14, several regions are in contact with the gate structure 12. Therefore, multiple channel regions are formed, which may increase the drive current of the Fin FET and improve the device performance. However, when process nodes shrink further, problems may occur on performance of the Fin FET device.

Therefore, there is a need to provide a Fin FET and a method for forming the Fin FET with improved device performance

### SUMMARY

According to various embodiments, there is provided a method for forming a Fin FET. The Fin FET can be formed by providing a dielectric layer on a semiconductor substrate. The dielectric layer and the semiconductor substrate can be etched to form a groove including a second sub-groove formed through the dielectric layer, and a first sub-groove formed in the semiconductor substrate and connected to the second sub-groove. A fin can then be formed in the groove. The fin can have a top surface over a top surface of the dielectric layer. A gate structure can then be formed at least partially around a length portion of the fin on the top surface of the dielectric layer.

According to various embodiments, there is also provided a Fin FET. The Fin FET can include a dielectric layer, a semiconductor substrate, a fin, and a gate structure. The dielectric layer can be disposed on the semiconductor substrate. The fin can be disposed through the dielectric layer and extended into a recessed portion of the semiconductor substrate. A top surface of the fin can be higher than a top surface of the dielectric layer. The gate structure can be formed at least partially around a length portion of the fin on the top surface of the dielectric layer.

In various embodiments, defects such as stacking fault and dislocations generated during formation of the fin can be concentrated in the recessed portion (or the first sub-grove) in the semiconductor substrate without influencing the gate leakage current of the Fin FET. The formed Fin FET has stable performance. The forming process is simple and the structure of the formed Fin FET is simple.

Optionally, the fin can further be annealed by an annealing process. Defects generated in the fin (including any defects generated in both the first sub-groove and the second sub-groove) are further eliminated. As a result, the gate leakage current is further decreased, and stability of the Fin FET is further improved.

Other aspects or embodiments of the present disclosure can be understood by those skilled in the art in light of the description, the claims, and the drawings of the present disclosure.

### BRIEF DESCRIPTION OF THE DRAWINGS

FIGS. 1-2 are three-dimensional structural views of a conventional fin field effect transistor;

FIG. 3 is a flow chart of an exemplary method for forming a fin field effect transistor according to various disclosed embodiments;

FIGS. 4-8 are cross-sectional views of intermediate structures illustrating a process for forming a fin field effect transistor according to various disclosed embodiments; and

FIG. 9 is a top view of the fin field effect transistor shown in FIG. 8 according to various disclosed embodiments.

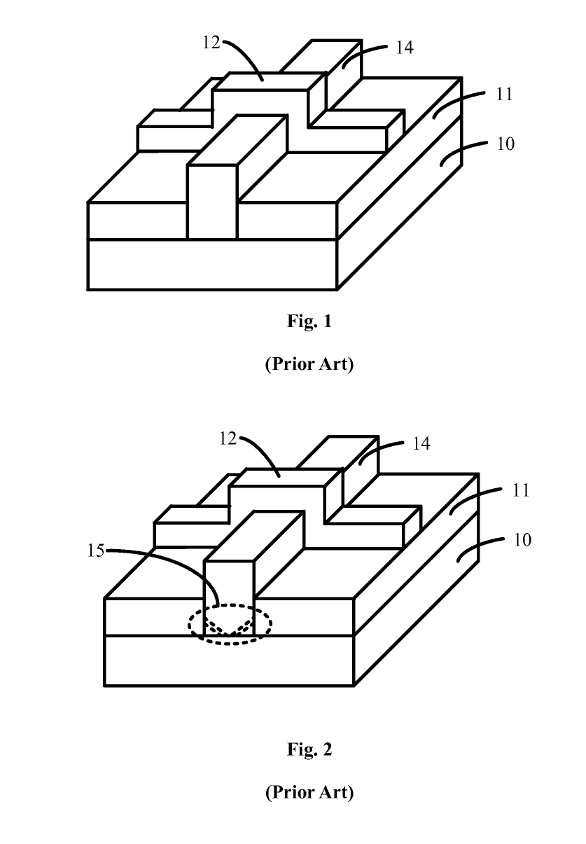

### DETAILED DESCRIPTION OF THE DISCLOSURE

Reference will now be made in detail to exemplary embodiments of the disclosure, which are illustrated in the accompanying drawings. Wherever possible, the same reference numbers will be used throughout the drawings to refer to the same or like parts. For illustration purposes, elements illustrated in the accompanying drawings are not drawn to scale, which are not intended to limit the scope of the present disclosure. In practical operations, each element in the drawings has specific dimensions such as a length, a width, and a depth.

Currently, when process nodes shrink further (e.g., sub 65 nm), problems may occur in performance of a Fin FET device. FIG. 2 is a three-dimensional structural view of a conventional fin field effect transistor. Applicants have discovered that defects or lattice defects, such as stacking fault and/or dislocations, are generated when a fin 14 is formed. As shown in FIG. 2, the defects may be formed at a bottom 15 of the fin 14 adjacent to the semiconductor substrate 10. Leakage current may thus be increased when the subsequently-formed Fin FET is in operation, and the device performance of the Fin FET is adversely affected.

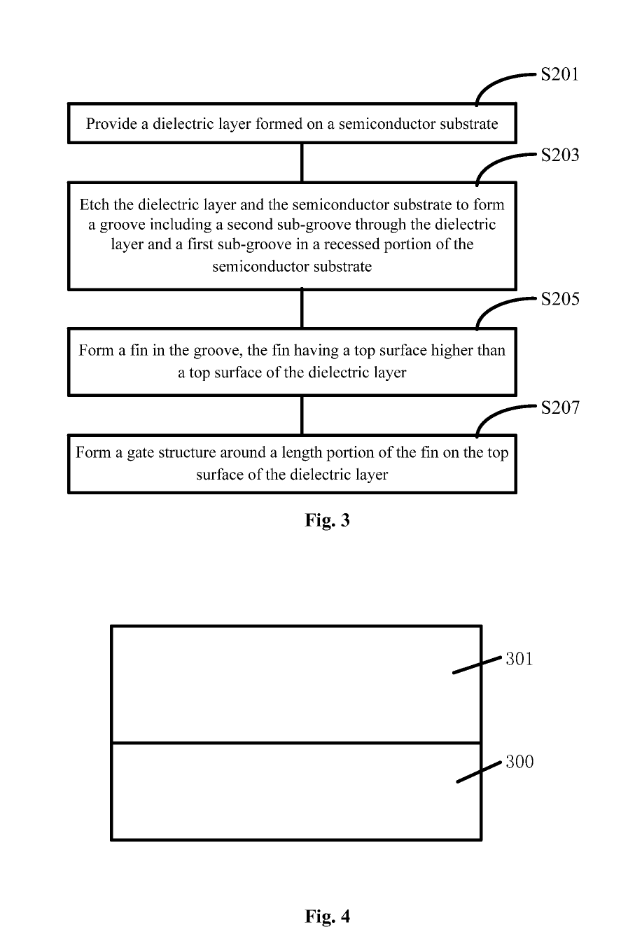

FIG. 3 is a flow chart of an exemplary method for forming a Fin FET (or a tri-gate FET) according to various disclosed embodiments. As disclosed herein, the formed Fin FET (or a tri-gate FET) can have improved device performance. For example, the exemplary method of FIG. 3 is illustrated herein in detail with reference to intermediate structures shown in FIGS. 4-8.

In Step S201 of FIG. 3 and referring to FIG. 4, a semiconductor substrate 300 is provided having a dielectric layer 301 formed thereon. The semiconductor substrate 300 is used for providing a working platform for the following processes. As an example, a material of the semiconductor substrate 300 is silicon.

The dielectric layer 301 is adapted for isolating a gate electrode layer to be formed from the semiconductor substrate 300. In one embodiment, the dielectric layer 301 has a thickness of about 130 nm, and a material of the dielectric layer 301 is SiO₂.

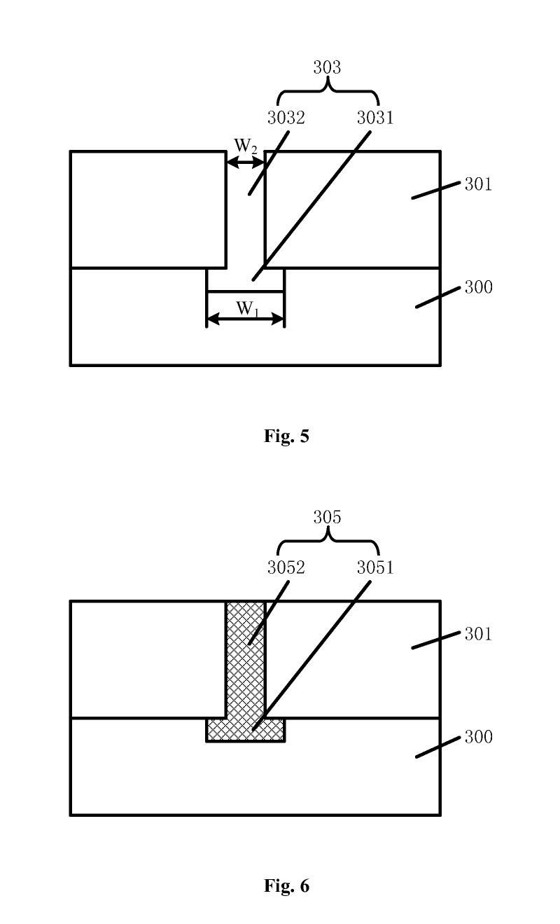

In Step S203 of FIG. 3 and referring to FIG. 5, the dielectric layer 301 and the semiconductor substrate 300 are etched to form a groove 303. The groove 303 includes a second sub-groove 3032 that passes through the dielectric layer 301 and a first sub-groove 3031 that is in the semiconductor substrate 300 and connected to the second sub-groove 3032. In one embodiment, the first sub-groove 3031 is a recessed portion formed in the semiconductor substrate 300 to trap defects, i.e., a recessed substrate is formed for trapping defects or lattice defects, e.g., including stacking fault and/or dislocations.

The groove 303 is subsequently filled up by a material to form a fin. However, when the fin is being formed, lattice defects, such as stacking fault and/or dislocations, may be generated. For example, when these defects are formed in a portion of the groove 303 located in the dielectric layer 301 (e.g., in the second sub-groove 3032), leakage current may be increased for the subsequently-formed Fin FET during its operation. Device performance thereof is adversely affected.

As disclosed herein, Fin FETs can be fabricated such that the above-mentioned defects can be controlled to be formed at locations that are not prone to increase the leakage current of the Fin FET during its operation. The device performance of the Fin FET can be improved. For example, during formation of the fin of the Fin FET, defects can be controlled to be formed mainly in the first sub-groove 3031 located in the semiconductor substrate 300, but not in the second sub-groove 3032 located through the dielectric layer 301. This is because the defects formed in the first sub-groove 3031 located in the semiconductor substrate 300 do not influence the gate leakage current of the subsequently-formed Fin FET.

That is, the subsequently-formed Fin FET can have low gate leakage current, which allows for stable device performance.

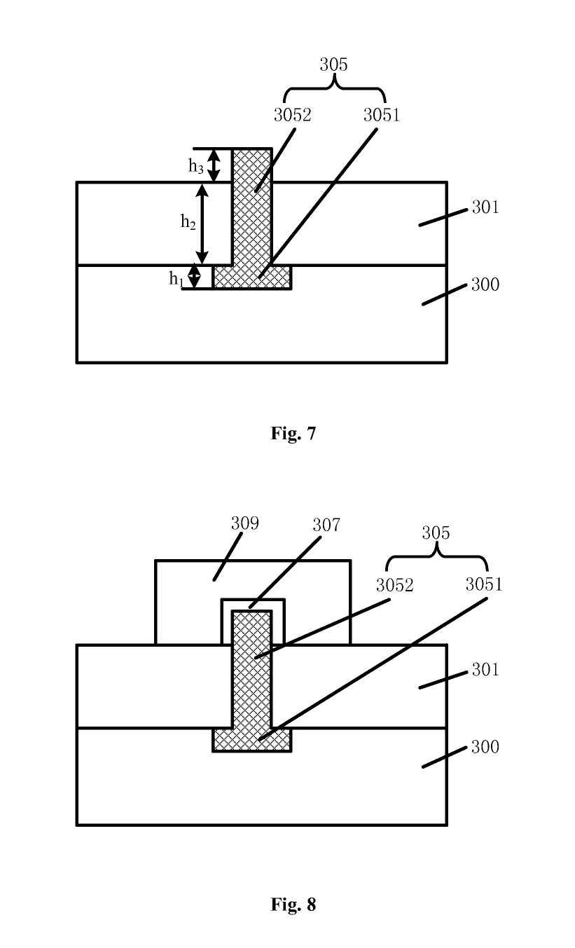

To control formation of the defects substantially in the first sub-groove 3031 located in the semiconductor substrate 300, the depth of the first sub-groove 3031 can be controlled. As shown in FIG. 7, the first sub-groove 3031 has a depth h₁ and the second sub-groove 3032 has a depth h₂ plus a depth h₃. As disclosed herein, a ratio of the depth (h₂ plus h₃) of the second sub-groove 3032 to the depth h₁ of the first sub-groove 3031 can be controlled to be greater than or equal to 5:1 (e.g., greater than or equal to 6:1; 6.5:1; or 7:1) such that defects can be substantially formed in the first sub-groove 3031 when the fin is formed in the first and second sub-grooves. The subsequently-formed Fin FET then has a minimum gate leakage current. In one example, the first sub-groove 3031 located in the semiconductor substrate 300 has a depth of about 20 nm.

Referring back to FIG. 5, the groove 303 is formed by an etching process, such as a dry etching and/or a wet etching. For example, the dielectric layer 301 is etched by firstly using a dry etching process to form the second sub-groove 3032 having a width W₂ (e.g., of about 20 nm or other suitable widths). The semiconductor substrate 300 exposed at the bottom of the second sub-groove 3032 is then etched by using a wet etching process to form the first sub-groove 3031 having a width W₁ (e.g., of about 60 nm or other suitable widths). The width W₁ of the first sub-groove 3031 is greater than or equal to the width W₂ of the second sub-groove 3032.

The dry etching process to form the second sub-groove 3032 is an isotropic etching process. A reagent used in the wet etching process to form the first sub-groove 3031 includes, e.g., tetramethylammonium hydroxide (TMAH) or potassium hydroxide (KOH) solution. When the wet etching is performed by using the TMAH solution, the process parameters are as follows: the mass fraction of the tetramethylammonium hydroxide is about 20% to about 40% of a total etching solution; and the etching temperature is about 80° C. to about 100° C. When the wet etching is performed by using the KOH solution, the process parameters are as follows: the mass fraction of the potassium hydroxide is about 30% to about 50% of a total etching solution, and the etching temperature is about 60° C. to about 80° C.

In other embodiments, the etching processes for forming the second sub-groove 3032 and the first sub-groove 3031 are not limited and any suitable etching processes may be encompassed herein in accordance with various disclosed embodiments.

In some embodiments, the width W₁ of the first sub-groove 3031 is greater than or equal to the width W₂ of the second sub-groove 3032, and is less than or equal to 3 times the width W₂ of the second sub-groove, i.e., W2<W1<3W2, to provide the formed Fin FET with high quality device performance.

In Step S205 of FIG. 3 and referring to FIG. 6, the groove including the first sub-groove 3031 and the second sub-groove 3032 is substantially filled with a material to form a fin 305. The material of the fin 305 includes one or more of SiGe, Ge, and/or a III-V group compound (such as InP and/or GaAs). As one example, the material of the fin 305 is SiGe.

The fin 305 is formed by a deposition process, such as a selective deposition process. The reaction gas used in the selective deposition process includes SiH₂Cl₂, GeH₄, and H₂. A deposition temperature is controlled in a range from about 500° C. to about 800° C., and the chamber pressure is controlled in a range from about 0.1 Torr to about 1 Torr. The formed fin 305 may have less or no defects and the device quality is stable. In one embodiment, the selective deposition process for forming the fin may use a deposition temperature of about 650° C. and a reaction pressure of about 0.5 Torr.

As shown in FIG. 6, the fin 305 includes a first sub-fin 3051 formed in the first sub-groove 3031 located in the semiconductor substrate 300 and a second sub-fin 3052 formed in the second sub-groove 3032 located in the dielectric layer 301. The fin 305 formed according to various embodiments can have defects substantially formed in the first sub-fin 3051 located in the semiconductor substrate 300, which does not increase the gate leakage current. The resulting Fin FET can have low gate leakage current with stable device performance.

Referring to FIG. 7, a portion of the dielectric layer 301 is etched away (removed) to expose a top portion of sidewall(s) of the fin 305 (e.g., the first sub-fin 3051). A top surface of the exposed fin 305 is, e.g., having a height h₃, above a top surface of the etched dielectric layer 301 to facilitate formation of a gate structure of a Fin FET. As an example, the portion of the dielectric layer 301 at both sides of the fin 305 is etched away (removed) by using a dry etching process.

In one example, the dielectric layer 301 of about 30 nm in thickness is removed, and the remaining etched dielectric layer 301 may have, e.g., a thickness of about 100 nm. That is, the exposed top portion of the fin has a height h₃ of about 30 nm over the top surface of the etched dielectric layer 301 for providing a platform for forming a gate structure.

In an embodiment, the disclosed method further includes: performing an annealing treatment to the fin 305 before etching the dielectric layer 301 to further eliminate formation of the defects in the fin 305. A gas used in the annealing treatment includes, e.g., H₂. The parameters for the annealing treatment are as follows: an annealing temperature ranges from about 600° C. to about 1000° C., and a reaction pressure ranges from about 0.5 torr to about 160 torr. After the annealing process is performed, the amount of the defects in the fin 305 is decreased to the minimum to provide the formed fin with high quality.

In another embodiment, the annealing process can be alternatively performed (or additionally performed) after the dielectric layer 301 is etched to expose the top portion of the fin 305.

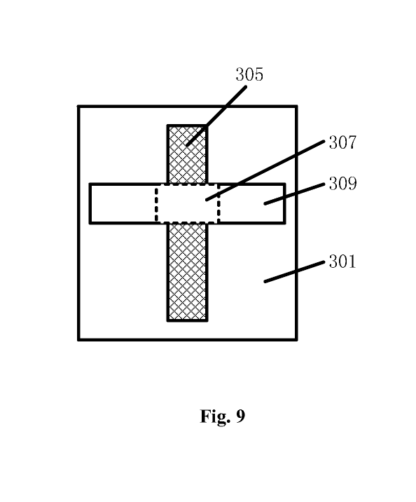

In Step S207 of FIG. 3 and referring to FIGS. 8-9, a gate structure is formed on the dielectric layer 301 and at least partially around a length portion of the fin 305. For example, the gate structure can be formed on an exposed top portion (e.g., inlcuding the top and the sidewalls) of the fin 305.

The gate structure includes a gate dielectric layer 307 formed on the surface of the dielectric layer 301 and partially around the fin 305 on the dielectric layer 301 and a gate electrode layer 309 covering the gate dielectric layer 307. In one embodiment, the material of the gate dielectric layer 307 is silicon oxide or high-K dielectrics, and the material of the gate electrode layer 309 is metal.

FIG. 9 is a top view of the fin field effect transistor shown in FIG. 8 according to various disclosed embodiments. As shown in FIG. 9, the gate structure, including the gate electrode layer 309 and the gate dielectric layer 307, is formed partially around a length portion of the fin 305 on the top surface of the dielectric layer 301. After the gate structure is formed, the partially exposed fin 305 is used for forming the source/drain on opposite sides of the gate structure.

In this manner, a Fin FET is formed. The formation method is simple having a dielectric layer on a semiconductor substrate. The dielectric layer is partially etched. A groove is formed to penetrate through the dielectric layer and extend into the semiconductor substrate, so that defects generated during formation of a fin are substantially formed in the semiconductor substrate without affecting gate leakage current. The formed Fin FET can have decreased gate leakage current and improved device performance.

Correspondingly, referring to FIG. 8, an exemplary Fin FET can include: a semiconductor substrate 300; a dielectric layer 301 on the semiconductor substrate 300; a fin 305 that penetrates through the dielectric layer 301 and extends into a portion of the semiconductor substrate 300, a top surface of the fin 305 being over a surface of the dielectric layer 301; and a gate structure disposed on the surface of the dielectric layer 301 and partially around a portion along a length (i.e., a length portion) of the fin 305 (e.g., on the top and the sidewalls of a length portion of the fin 305).

In one embodiment, a material of the semiconductor substrate 300 is silicon, and the semiconductor substrate 300 is used for providing a platform for forming the Fin FET. The dielectric layer 301 is used for isolating the gate electrode layer 309 from the semiconductor substrate 300, and proving a platform for forming a groove. As an example, the material of the dielectric layer 301 is SiO₂.

The fin 305 can be formed by a material having a different lattice constant from the material of the semiconductor substrate 300. The fin 305 can be lattice mismatched with the semiconductor substrate 300. The material of the fin 305 includes one or more of SiGe, Ge, and/or a III-V group compound. In one embodiment, the semiconductor substrate 300 is Si and the fin 305 is SiGe or Ge or a stacked structure of SiGe and Ge. In another embodiment, the semiconductor substrate 300 is Si and the fin 305 is a III-V group compound.

The fin 305 includes a first sub-fin 3051 in the semiconductor substrate 300 and a second sub-fin 3052 through the dielectric layer 301. A top portion of the fin 305 is exposed over the top surface of the dielectric layer 301. The ratio of a height h₂ of the second sub-fin 3052 (as shown in FIG. 7) to a height h₁ of the first sub-fin 3051 (as shown in FIG. 7) is greater than or equal to 5:1. A width W₁ of the first sub-fin 3051 (as shown in FIG. 5) is less than or equal to 3 times a width W₂ of the second sub-fin 3052 (as shown in FIG. 5), and is greater than or equal to the width W₂ of the second sub-fin 3052 (as shown in FIG. 5). The defects generated during formation of the fin 305 mainly concentrate at the first sub-fin 3051 in the semiconductor substrate 300, at which the defects do not cause gate leakage current when the Fin FET is in operation. The Fin FET thus has low gate leakage current and stable device performance.

In a certain embodiment, the material of the fin 305 is SiGe. In various embodiments, the first sub-fin 3051 has a width W₁ of about 60 nm and a height h₁ of about 20 nm located in the semiconductor substrate 300; the second sub-fin 3052 has a width W₂ of about 20 nm and a height h₂ of about 100 nm located through the etched dielectric layer 301, and has a height h₃ of the exposed top portion of the fin 305 over a top surface of the etched dielectric layer 301 of about 30 nm.

The gate structure includes a gate dielectric layer 307 formed on the top surface of the etched dielectric layer 301 and on the top and the sidewalls of the fin 305; and a gate electrode layer 309 covering the gate dielectric layer 307. In one embodiment, the material of the gate dielectric layer 307 is SiO₂ or high-K dielectrics, and the material of the gate electrode layer 309 is metal.

The disclosed Fin FET has a simple structure, and defects formed during formation of the fin 305 are mainly formed at the first sub-fin 3051 in the semiconductor substrate 300, at which the defects do not cause gate leakage current when the Fin FET is in operation. The Fin FET thus has low gate leakage current and stable device performance.

To form the disclosed Fin FET, the dielectric layer and the semiconductor substrate are etched to form the first sub-groove and the second sub-groove; the first sub-groove is obtained by etching the semiconductor substrate. The defect generated during formation of the fin mainly concentrates at the locations corresponding to the first groove, where the defects do not cause gate leakage current when the Fin FET is in operation. The Fin FET thus has low gate leakage current and stable device performance.

Further, after the fin is formed, the method further includes: performing an annealing process to anneal the fin prior and/or before etching of the dielectric layer. The annealing process further eliminates the defects generated in the fin (e.g., including defects at the locations corresponding to the first sub-groove and/or the second sub-groove). As such, gate leakage current is further decreased, and stability of the Fin FET is further improved.

The embodiments disclosed herein are exemplary only. Other applications, advantages, alternations, modifications, or equivalents to the disclosed embodiments are obvious to those skilled in the art and are intended to be included within the scope of the present disclosure.

What is claimed is:

1. A method for forming a fin field effect transistor, comprising:
providing a dielectric layer on a semiconductor substrate;
etching the dielectric layer and the semiconductor substrate to form a groove, the groove comprising a second sub-groove, formed through the dielectric layer, and a first sub-groove, formed in the semiconductor substrate and connected to the second sub-groove;
forming a fin in the groove, wherein the fin has a top surface over a top surface of the dielectric layer; and
forming a gate structure at least partially around a length portion of the fin on the top surface of the dielectric layer.

2. The method according to claim 1, wherein a ratio of a depth of the second sub-groove to a depth of the first sub-groove is greater than or equal to 5:1.

3. The method according to claim 1, wherein a width of the first sub-groove is less than or equal to 3 times a width of the second sub-groove, and is greater than or equal to the width of the second sub-groove.

4. The method according to claim 1, wherein the first sub-groove is formed by a dry etching process or a wet etching process, and the second sub-groove is formed by a dry etching process.

5. The method according to claim 4, wherein a reagent used in the wet etching process is tetramethylammonium hydroxide or potassium hydroxide.

6. The method according to claim 5, wherein the wet etching process using tetramethylammonium hydroxide includes a mass fraction of tetramethylammonium hydroxide ranging from about 20% to about 40% of a total etching solution, and an etching temperature ranging from about 80° C. to about 100° C.

7. The method according to claim 5, wherein the wet etching process using potassium hydroxide includes a mass fraction of potassium hydroxide ranging from about 30% to about 50% of a total etching solution, and an etching temperature ranging from about 60° C. to about 80° C.

8. The method according to claim 1, wherein the fin is formed by a selective deposition process.

9. The method according to claim 8, wherein the selective deposition process is performed at a temperature ranging from about 500° C. to about 800° C., a reaction pressure ranging from about 0.1 torr to about 1 torr, and a reaction gas comprising SiH₂Cl₂, GeH₄, and H₂.

10. The method according to claim 1, wherein the fin is made of a material comprising one or more of SiGe, Ge, and a III-V group compound, and the semiconductor substrate is made of a material of silicon.

11. The method according to claim 1, further comprising: performing an annealing process to anneal the fin.

12. The method according to claim 11, wherein a gas used in the annealing process comprises H₂.

13. The method according to claim 11, wherein the annealing process uses an annealing temperature ranging from about 600° C. to about 1000° C., and a reaction pressure ranging from about 0.5 torr to about 160 torr.

14. The method according to claim 1, wherein forming a fin in the groove comprises:
filling up the groove by a deposition process to form the fin, and
etching the dielectric layer to expose a top portion of the fin.

15. The method according to claim 1, wherein the formation of the gate structure comprises:
forming a gate dielectric layer partially around the length portion of the fin on the top surface of the dielectric layer; and
forming a gate electrode layer covering the gate dielectric layer.

16. A fin field effect transistor, comprising:
a semiconductor substrate;
a dielectric layer disposed on the semiconductor substrate;
a fin disposed through the dielectric layer and extended into a recessed portion of the semiconductor substrate, wherein a top surface of the fin is higher than a top surface of the dielectric layer; and
a gate structure partially around a length portion of the fin on the top surface of the dielectric layer.

17. The transistor according to claim 16, wherein the fin comprises a first sub-fin in the recessed portion of the semiconductor substrate and a second sub-fin through the dielectric layer, and wherein a ratio of a height of the second sub-fin to a height of the first sub-fin is greater than or equal to 5:1.

18. The transistor according to claim 17, wherein a width of the first sub-fin is less than 3 times a width of the second sub-fin, and is greater than or equal to the width of the second sub-fin.

19. The transistor according to claim 16, wherein the fin is made of a material comprising one or more of SiGe, Ge, and a III-V group compound, and the semiconductor substrate is made of a material of silicon.

20. The transistor according to claim 16, wherein the gate structure comprises:
a gate dielectric layer partially around the length portion of the fin on the top surface of the dielectric layer; and
a gate electrode layer covering the gate dielectric layer.
